(19) United States
(12) Patent Application Publication
(10) Pub. No.: US 2024/0389413 A1
(43) Pub. Date: Nov. 21, 2024

(54) Display Panel and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Hui LU, Beijing (CN); Changchang LIU, Beijing (CN); Hongting LU, Beijing (CN); Ling SHI, Beijing (CN)

(21) Appl. No.: 18/691,872

(22) PCT Filed: Aug. 7, 2023
(86) PCT No.: PCT/CN2023/111467

§ 371 Date: Mar. 13, 2024

(30) Foreign Application Priority Data
Aug. 29, 2022 (CN) 202211064682.3

(51) Int. Cl. H10K 59/131; G09G 3/3233

(52) U.S. Cl. CPC H10K 59/131; G09G 3/3233; G09G 2300/0426; G09G 2300/0819; G09G 2300/0842; G09G 2300/0861; G09G 2310/08; G09G 2330/021

(57) ABSTRACT

A display panel and a display apparatus. The display panel comprises a display region and a peripheral region located on one side of the display region. The peripheral region comprises a bent region and a fanout region, the fanout region being located on the side of the bent region away from the display region. The display panel comprises: a substrate and, arranged on the substrate, circuit units arranged in an array, a plurality of data signal lines extending in a first direction, and a plurality of data fanout lines located in the fanout region, said data signal lines at least extending to the bent region from the display region, and said data signal lines being respectively electrically connected to the circuit units and the data fanout lines.

### CROSS-REFERENCE TO RELATED APPLICATION

The present disclosure is a U.S. National Phase Entry of International Application No. PCT/CN2023/111467 having an international filing date of Aug. 7, 2023, which claims priority to Chinese Patent Application No. 202211064682.3, filed to the CNIPA on Aug. 29, 2022 and entitled “Display Panel and Display Apparatus”. The above-identified applications are incorporated herein by reference in their entireties.

### TECHNICAL FIELD

The present disclosure relates to, but is not limited to, the field of display technologies, and more particularly, to a display panel and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described herein in detail. This summary is not intended to limit the protection scope of the claims.

In a first aspect, the present disclosure provides a display panel including a display region and a peripheral region located at a side of the display region, wherein the peripheral region includes a bending region and a fan-out region; the fan-out region is located at a side of the bending region away from the display region; the display panel includes: a base substrate, circuit units arranged in an array on the base substrate, a plurality of data signal lines extending along a first direction, and a plurality of data fan-out lines located in the fan-out region.

The data signal lines extend from the display region to at least the bending region, and are electrically connected with the circuit units and the data fan-out lines, respectively.

In an exemplary implementation, the display panel further includes a plurality of high-voltage power supply lines extending along the first direction, and at least one high-voltage power supply line extending from the display region to the fan-out region.

A plurality of circuit units extending along the first direction are a column of circuit units, one high-voltage power supply line is electrically connected with a column of circuit units, and the at least one high-voltage power supply line is electrically connected with a plurality of columns of circuit units.

In an exemplary implementation, the display panel further includes a plurality of light emitting devices and a plurality of low-voltage power supply lines extending along the first direction, wherein the low-voltage power supply lines extend from the display region to the fan-out region, and the circuit unit is electrically connected with the light emitting devices.

The plurality of low-voltage power supply lines are electrically connected with cathodes of the light emitting devices connected to a plurality of columns of circuit units.

In an exemplary implementation, the number of high-voltage power supply lines and the number of low-voltage power supply lines extending to the fan-out region are equal to the number of data signal lines, respectively.

The i-th high-voltage power supply line and the i-th low-voltage power supply line are respectively located at opposite sides of the i-th data signal line, wherein 1≤i≤N, and N is the number of data signal lines.

In an exemplary implementation, the sum of the number of high-voltage power supply lines and the number of low-voltage power supply lines extending to the fan-out region is equal to the number of data signal lines.

The m-th high-voltage power supply line extending to the fan-out region is connected to the (2m−1)-th column of circuit units, the m-th high-voltage power supply line extending to the fan-out region is located between the (2m−1)-th data signal line and the (2m)-th data signal line, the n-th low-voltage power supply line is located between the (2n)-th data signal line and the (2n+1)-th data signal line, or the m-th high-voltage power supply line extending to the fan-out region is connected to the (2m)-th column of circuit units, the m-th high-voltage power supply line extending to the fan-out region is located between the (2m)-th data signal line and the (2m+1)-th data signal line, the n-th low-voltage power supply line is located between the (2n−1)-th data signal line and the (2n)-th data signal line, wherein 1≤m≤N1, 1≤n≤N2, N1 is the number of high-voltage power supply lines extending to the fan-out region, and N2 is the number of low-voltage power supply lines.

In an exemplary implementation, the display panel further includes: a high-voltage signal line located in the fan-out region and extending along a second direction, wherein the first direction intersects with the second direction.

The high-voltage signal line is electrically connected with at least one high-voltage power supply line extending to the fan-out region, and an orthographic projection of the high-voltage signal line on the base substrate is overlapped with orthographic projections of the data fan-out lines on the base substrate.

A length of the high-voltage signal line along the first direction is greater than length of the high-voltage power supply lines along the second direction.

In an exemplary implementation, the display panel further includes: a low-voltage signal line located in the fan-out region and extending along the second direction.

The low-voltage signal line is electrically connected with a plurality of low-voltage power supply lines, and an orthographic projection of the low-voltage signal line on the base substrate is overlapped with the orthographic projections of the data fan-out lines on the base substrate.

A length of the low-voltage signal line along the first direction is greater than lengths of the low-voltage power supply lines along the second direction.

In an exemplary implementation, the low-voltage signal line and the high-voltage signal line are arranged in different layers.

In the fan-out region, the low-voltage signal line is located at a side of the high-voltage signal line away from the display region.

In an exemplary implementation, the peripheral region further includes: a bending transition region, and the bending transition region is located between the display region and the bending region.

The data signal lines include: a first data signal line located at least in the display region, a second data signal line located at least in the bending transition region and a third data signal line located at least in the bending region.

The second data signal line is arranged in a layer different from the first data signal line and the third data signal line respectively, the third data signal line is arranged in a layer different from the data fan-out line, an orthographic projection of the second data signal line on the base substrate is partially overlapped with an orthographic projection of the first data signal line and an orthographic projection of the third data signal line on the base substrate, respectively, the orthographic projection of the third data signal line on the base substrate is partially overlapped with the orthographic projections of the data fan-out lines on the base substrate, the second data signal line is electrically connected with the first data signal line and the third data signal line, respectively, the first data signal line is electrically connected with the circuit units, and the third data signal line is electrically connected with the data fan-out lines.

In an exemplary implementation, the high-voltage power supply line includes a first high-voltage power supply line located at least in the display region, a second high-voltage power supply line located at least in the bending transition region and a third high-voltage power supply line located at least in the bending region and the fan-out region.

The second high-voltage power supply line is arranged in a layer different from the first high-voltage power supply line and the third high-voltage power supply line, respectively, the third high-voltage power supply line is arranged in the same layer with the high-voltage signal line, an orthographic projection of the second high-voltage power supply line on the base substrate is partially overlapped with an orthographic projection of the first high-voltage power supply line on the base substrate and an orthographic projection of the third high-voltage power supply line on the base substrate, respectively, the second high-voltage power supply line is electrically connected with the first high-voltage power supply line and the third high-voltage power supply line, respectively, the first high-voltage power supply line is electrically connected with the circuit units, and the third high-voltage power supply line is electrically connected with the high-voltage signal line.

In an exemplary implementation, the low-voltage power supply lines include a first low-voltage power supply line located at least in the display region and the bending transition region and a second low-voltage power supply line located at least in the bending region and the fan-out region.

The first low-voltage power supply line and the second low-voltage power supply line are arranged in different layers, the second low-voltage power supply line and the low-voltage signal line are arranged in the same layer, an orthographic projection of the first low-voltage power supply line on the base substrate is partially overlapped with orthographic projections of cathodes of the light emitting devices on the base substrate and an orthographic projection of the second low-voltage power supply line on the base substrate, respectively, the first low-voltage power supply line is electrically connected with the cathodes of the light emitting devices and the second low-voltage power supply line, respectively, and the second low-voltage power supply line is electrically connected with the low-voltage signal line.

In an exemplary implementation, the display panel further includes a drive circuit layer and a light emitting structure layer arranged on the base substrate, wherein the drive circuit layer is provided with a circuit unit, a data signal line, a data fan-out line, a high-voltage power supply line, a low-voltage power supply line, a high-voltage signal line and a low-voltage signal line, the light emitting structure layer is provided with a light emitting device, and the drive circuit layer includes a first conductive layer, a second conductive layer, a third conductive layer and a fourth conductive layer which are sequentially stacked on the base substrate.

The first data signal line is located in the third conductive layer and/or the fourth conductive layer, the second data signal line is located in the first conductive layer or the second conductive layer, the third data signal line is located in the third conductive layer or the fourth conductive layer, and the data fan-out line is located in the first conductive layer or the second conductive layer.

In an exemplary implementation, the first high-voltage power supply line is located in the third conductive layer and/or the fourth conductive layer, the second high-voltage power supply line is located in the first conductive layer or the second conductive layer, and the third high-voltage power supply line is located in the third conductive layer or the fourth conductive layer.

In an exemplary implementation, the first low-voltage power supply line is located in the first conductive layer or the second conductive layer; and the second low-voltage power supply line is located in the third conductive layer or the fourth conductive layer.

In an exemplary implementation, the peripheral region further includes a drive chip bonding region located at a side of the fan-out region away from the display region, the drive chip bonding region includes a control chip, and the display panel further includes at least one high-voltage connection line extending along the first direction and at least one low-voltage connection line extending along the first direction.

The high-voltage connection line is electrically connected with the high-voltage signal line and the control chip, respectively, and the low-voltage connection line is electrically connected with the low-voltage signal line and the control chip, respectively.

In an exemplary implementation, the high-voltage connection line is arranged on the same layer as the high-voltage signal line, and the low-voltage connection line is arranged on the same layer as the low-voltage signal line.

In second aspect, the present disclosure also provides a display apparatus including the display panel described above.

Other aspects of the present disclosure may be comprehended after the drawings and the detailed descriptions are read and understood.

### BRIEF DESCRIPTION OF DRAWINGS

Accompany drawings are used to provide further understanding of the technical solution of the present disclosure, and form a part of the description. The accompany drawings and embodiments of the present disclosure are adopted to explain the technical solution of the present disclosure, but do not form limitations on the technical solution of the present disclosure.

FIG. 1 is a schematic diagram of a structure of a display apparatus.

FIG. 2 is a schematic diagram of a structure of a display panel.

FIG. 3 is a first schematic diagram of a planar structure of a display region in a display panel.

FIG. 4 is a second schematic diagram of a planar structure of a display region in a display panel.

FIG. 5 is a third schematic diagram of a planar structure of a display region in a display panel.

FIG. 6 is a schematic diagram of a sectional structure of the display panel provided in FIG. 3 along the A-A direction.

FIG. 7A is a schematic diagram of an equivalent circuit of a pixel circuit.

FIG. 7B is a working timing diagram of a pixel circuit.

FIG. 8 is a first schematic diagram of a structure of a display panel according to an embodiment of the present disclosure.

FIG. 9 is a second schematic diagram of a structure of a display panel according to an embodiment of the present disclosure.

FIG. 10 is a first schematic diagram of a partial film layer of a display panel.

FIG. 11 is a second schematic diagram of a partial film layer of a display panel.

FIG. 12 is a third schematic diagram of a partial film layer of a display panel.

### DETAILED DESCRIPTION

The embodiments of the present disclosure will be described below with reference to the drawings in detail. Implementation modes may be implemented in multiple different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and a mode of the present disclosure is not limited to shapes, numerical values, or the like shown in the drawings.

Ordinal numerals “first”, “second”, “third”, etc., in the specification are set not to form limits on numbers but only to avoid confusion between composition elements. In the present disclosure, “a plurality of” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are needed to have specific orientations and be structured and operated with the specific orientations but only to easily and simply describe the present specification, and thus should not be understood as limitations on the present disclosure. The positional relationships between the constituent elements are changed as appropriate according to a direction with which the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, “electrical connection” includes connection of composition elements through an element with some electrical effection. The “element having some electrical effection” is not particularly limited as long as electrical signals between the connected constituent elements may be transmitted. Examples of the “element having some electrical effection” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the specification, “about” and “substantially” refer to that a boundary is not defined strictly and a case within a process and measurement error range is allowed. In the specification, “substantially the same” refers to a case where numerical values differ by less than 10%.

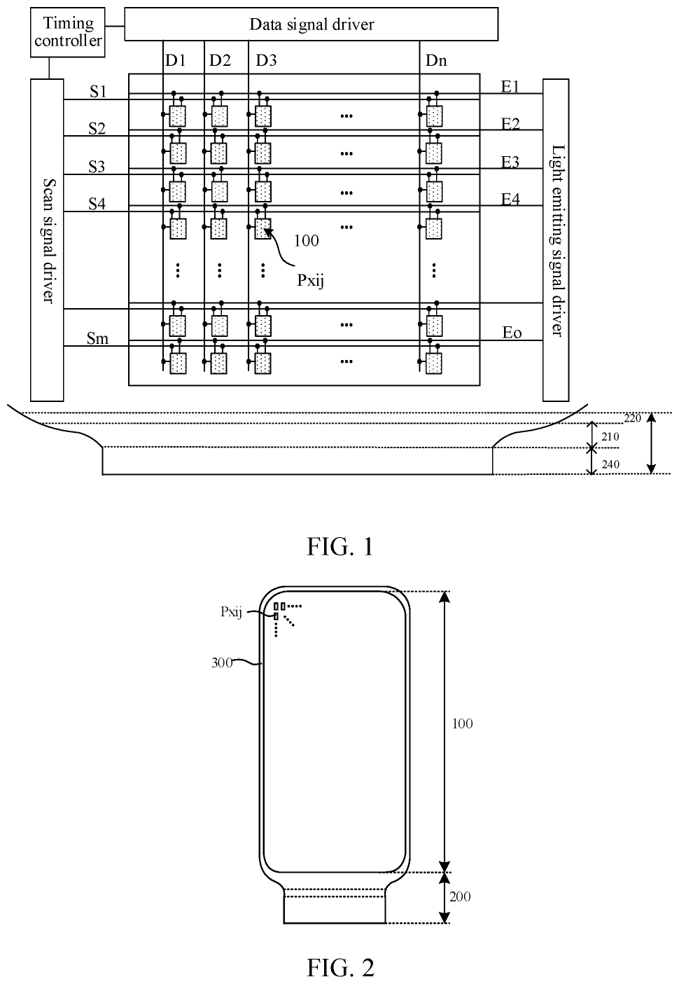

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively. The data driver is respectively connected with a plurality of data signal lines (e.g., D1 to Dn), the scan driver is respectively connected with a plurality of scan signal lines (e.g., S1 to Sm), and the light emitting driver is respectively connected with a plurality of light emitting signal lines (e.g., E1 to Eo). Among them, n, m, and o may be natural numbers. The pixel array may include a plurality of sub-pixels Pxij, wherein i and j may be natural numbers. At least one sub-pixel Pxij may include a circuit unit and a light emitting device connected with the circuit unit. The circuit unit may at least include a pixel circuit which may be connected with a scan signal line, a light emitting signal line, and a data signal line, respectively.

In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value by using a clock signal, and apply a data voltage corresponding to the gray scale value to the data signal lines D1 to Dn by taking a pixel column as a unit. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register, and may generate a scan signal in a manner of sequentially transmitting a scan start signal provided in a form of an on-level pulse to a next-stage circuit under control of a clock signal. The light emitting driver may generate a light emitting control signal to be provided to the light emitting signal lines E1, E2, E3, . . . , and Eo by receiving the clock signal, the emission stop signal, etc. from the timing controller. For example, the light emitting driver may sequentially provide an emission signal with an off-level pulse to the light emitting signal lines E1 to Eo. For example, the light emitting driver may be constructed in a form of a shift register and generate a light emitting control signal in a manner of sequentially transmitting an emission stop signal provided in a form of an off-level pulse to a next-stage circuit under control of a clock signal.

FIG. 2 is a schematic diagram of a structure of a display panel. As shown in FIG. 1 and FIG. 2, the display panel may include a display region 100, a peripheral region 200 located at a side of the display region 100, and a bezel region 300 located at other sides of the display region 100. In some examples, the display region 100 may be a planar region including a plurality of sub-pixels Pxij that form a pixel array, the plurality of sub-pixels Pxij may be configured to display a dynamic picture or a static image, and the display region 100 may be referred to as an Active region (AA). In some examples, the display panel may be a flexible substrate, and accordingly the display panel may be deformable, for example, may be crimped, bent, folded, or curled.

In an exemplary implementation, a peripheral region 200 may include a fan-out region 220, a bending region 210, a driver chip region 240, and a bonding pin region that are arranged sequentially along a direction away from the display region 100. The fan-out region introduces signal lines of integrated circuits and bonding pads in the peripheral region into a wider display region in a fan-out (Fanout) trace manner. The fan-out region at least includes a data fan-out (Fanout) line, and a plurality of data fan-out lines are configured to be connected with data signal lines in a fan-out trace manner. The bending region may include a composite insulation layer provided with a groove, and is configured to enable the drive chip bonding region and the bonding pin region to be bent to a back of the display region 100. An Integrated Circuit (IC) may be arranged in the drive chip bonding region, and the integrated circuit may be configured to be connected with the plurality of data fan-out lines. The bonding pin region may include a bonding pad, and the bonding pad may be configured to be bonded and connected with an external Flexible Printed Circuit (FPC). In an exemplary implementation mode, the bezel region 300 may include a circuit region, a power supply line region, and a crack dam region, and a cutting region which are sequentially arranged along the direction away from the display region 100. The circuit region is connected to the display region 100 and may include at least a gate drive circuit, the gate drive circuit is connected with the scan signal line, the reset signal line, and the light emitting signal line that are connected with the pixel circuit in the display region 100. The power supply line region is connected to the circuit region and may at least include a bezel power supply lead line that extends along a direction parallel to an edge of the display region and is connected with a cathode in the display region 100. The crack dam region is connected to the power supply line region and may at least include a plurality of cracks arranged on the composite insulation layer. The cutting region is connected to the crack dam region and may at least include a cutting groove arranged on the composite insulation layer, and the cutting groove is configured such that a cutting device cuts along the cutting groove respectively after preparation of all film layers of the display panel are completed.

In an exemplary implementation mode, the fan-out region in the peripheral region 200 and the power supply line region in the bezel region 300 may be provided with a first isolation dam and a second isolation dam, the first isolation dam and the second isolation dam may extend along a direction parallel to the edge of the display region 100, thus forming an annular structure surrounding the display region 100. The edge of the display region is an edge of the display region 100 at a side close to the peripheral region 200 or the bezel region 300.

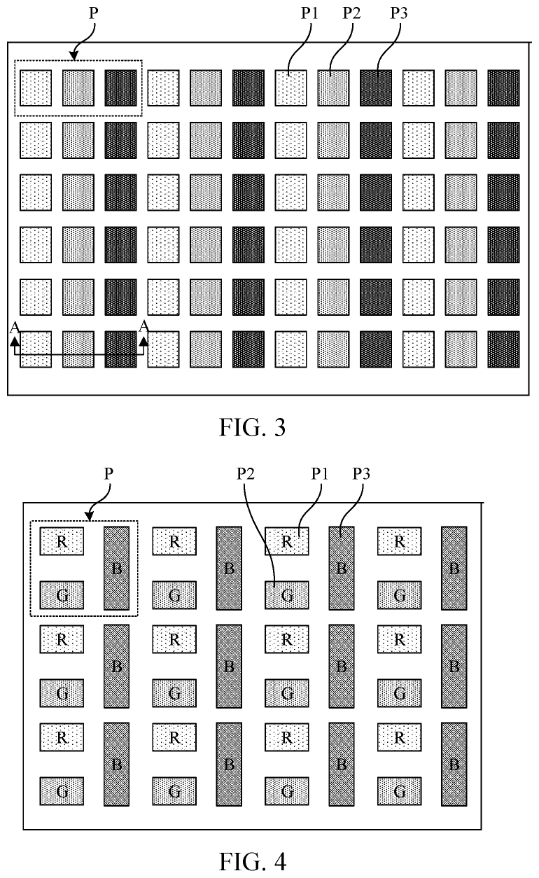

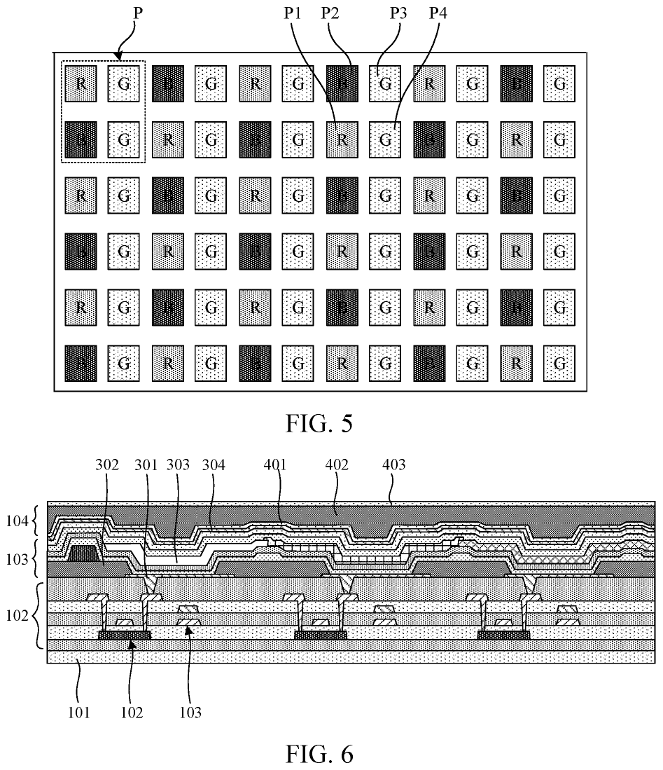

FIG. 3 is a first schematic diagram of a planar structure of a display region in a display panel, FIG. 4 is a second schematic diagram of a planar structure of a display region in a display panel, and FIG. 5 is a third schematic diagram of a planar structure of a display region in a display panel. As shown in FIG. 3 to FIG. 5, the display panel may include a plurality of pixel units P arranged in a matrix. At least one pixel unit P may include three sub-pixels or four sub-pixels. FIG. 3 and FIG. 4 are illustrated by taking that a pixel unit includes three sub-pixels as an example. FIG. 5 is illustrated by taking that a pixel unit includes four sub-pixels as an example. Each sub-pixel may include a circuit unit and a light emitting device, the circuit unit may at least include a pixel circuit which is connected with a scan signal line, a data signal line, and a light emitting signal line respectively, and the pixel circuit may be configured to receive a data voltage transmitted by the data signal line and output a corresponding current to the light emitting device under control of the scan signal line and the light emitting signal line. The light emitting device in each sub-pixel is connected with a pixel circuit of the sub-pixel where the light emitting device is located, and the light emitting device is configured to emit light with corresponding brightness in response to a current output by the pixel circuit of the sub-pixel where the light emitting device is located.

In an exemplary implementation, a light emitting device of the sub-pixel may have a shape of a rectangle, a rhombus, a pentagon, or a hexagon.

In an exemplary implementation, as shown in FIG. 3 and FIG. 4, at least one pixel unit P may include a first sub-pixel P1 emitting first color light, a second sub-pixel P2 emitting second color light, and a third sub-pixel P3 emitting third color light. For example, the first sub-pixel P1 may be a red sub-pixel (R) emitting red light, the second sub-pixel P2 may be a blue sub-pixel (B) emitting blue light, and the third sub-pixel P3 may be a green sub-pixel (G) emitting green light. The light emitting devices of three sub-pixels may be arranged side by side horizontally, side by side vertically, or in a manner like a Chinese character “ [symbol] ”, etc., which is not limited here in the present disclosure. FIG. 3 is illustrated by an example that the light emitting elements of three sub-pixels are arranged horizontally side by side. FIG. 4 is illustrated by an example that three sub-pixel light emitting elements are arranged in a manner like a Chinese character “ [symbol] ”. In an exemplary implementation, as shown in FIG. 5, at least one pixel unit P may include a first sub-pixel Pl emitting first color light, a second sub-pixel P2 emitting second color light, and a third sub-pixel P3 and a fourth sub-pixel P4 emitting third color light. The first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation, the light emitting devices of four sub-pixels may be arranged in a manner of a diamond to form an RGBG pixel arrangement. In another exemplary implementation, the light emitting devices of four sub-pixels may be arranged side by side horizontally, side by side vertically, or in a manner of a square, etc., which is not limited here in the present disclosure. FIG. 5 is illustrated by an example that the light emitting elements of four sub-pixels are arranged in a manner of a square.

FIG. 6 is a schematic diagram of a sectional structure of the display panel provided in FIG. 3 along the A-A direction, which illustrates a structure of three sub-pixels of the display panel. Referring to FIG. 6, on a plane perpendicular to the display substrate, the display substrate may include a drive circuit layer 102 arranged on a base substrate 101, a light emitting structure layer 103 arranged at a side of the drive circuit layer 102 away from the base substrate 101, and an encapsulation structure layer 104 arranged at a side of the light emitting structure layer 103 away from the base substrate 101. In some possible implementations, the display substrate may include another film layer, such as a touch structure layer, which is not limited in the present disclosure.

In an exemplary implementation, the base substrate 101 may be a flexible base substrate, or may be a rigid base substrate. The rigid base substrate may include, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible base substrate may include a first flexible material layer, a first inorganic material layer, a semiconductor layer, a second flexible material layer and a second inorganic material layer stacked on the glass carrier plate. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx) or Silicon Oxide (SiOx), etc. to improve an anti-water-oxygen capability of the base substrate. The first inorganic material layer and the second inorganic material layer are called as barrier layers, and the semiconductor layer may be a polycrystalline Silicon (p-Si) layer. In an exemplary implementation, taking a laminated structure of PI1/Barrier1/p-Si/PI2/Barrier2 as an example, its preparation process may include: firstly, coating a layer of polyimide on the glass carrier plate, curing it into a film to form a first flexible (PI1) layer; then, depositing a layer of barrier thin film on the first flexible layer to form a first barrier (Barrier1) layer covering the first flexible layer; then depositing a layer of amorphous silicon thin film on the first barrier layer to form an amorphous silicon (a-si) layer covering the first barrier layer, and forming a polysilicon layer through a process such as excimer laser annealing; after that, coating a layer of polyimide on the polysilicon layer, curing it into a film to form a second flexible (PI2) layer; then, depositing a layer of barrier thin film on the second flexible layer to form a second barrier (Barrier2) layer covering the second flexible layer, thereby completing preparation of the base substrate.

In an exemplary implementation, the drive circuit layer 102 of each sub-pixel may include a plurality of transistors and a storage capacitor, which constitute a pixel drive circuit. In FIG. 6, only one transistor and one storage capacitor 103 are taken as an example. The light emitting structure layer 103 may include an anode 301, a pixel definition layer 302, an organic light emitting layer 303 and a cathode 304. The anode 301 is connected to a drain electrode of a drive transistor 102 through a via, the organic light emitting layer 303 is connected to the anode 301, and the cathode 304 is connected to the organic light emitting layer 303. The organic light emitting layer 303 emits light of corresponding color under driving by the anode 301 and the cathode 304. The encapsulation structure layer 104 may include a first encapsulation layer 401, a second encapsulation layer 402, and a third encapsulation layer 403 which are stacked, the first encapsulation layer 401 and the third encapsulation layer 403 may be made of an inorganic material, the second encapsulation layer 402 may be made of an organic material, and the second encapsulation layer 402 is arranged between the first encapsulation layer 401 and the third encapsulation layer 403, which may ensure that external water vapor cannot enter the light emitting structure layer 103.

In an exemplary implementation, the touch structure layer of each sub-pixel may include a first touch insulation layer arranged on the encapsulation structure layer, a first touch metal layer on the first touch insulation layer, a second touch insulation layer covering the first touch metal layer, a second touch metal layer arranged on the second touch insulation layer, and a touch protective layer covering the second touch metal layer. The first touch metal layer may include a plurality of bridge electrodes, the second touch metal layer may include a plurality of first touch electrodes and second touch electrodes, and the first touch electrodes or the second touch electrodes may be connected with the bridge electrodes through a via.

In an exemplary implementation mode, the organic emitting layer may include an Emitting Layer (EM), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In some examples, one or more layers of hole injection layers, hole transport layers, electron block layers, hole block layers, electron transport layers, and electron injection layers of all sub-pixels may be respectively connected together to be a common layer. Emitting layers of adjacent sub-pixels may be overlapped slightly, or may be mutually isolated.

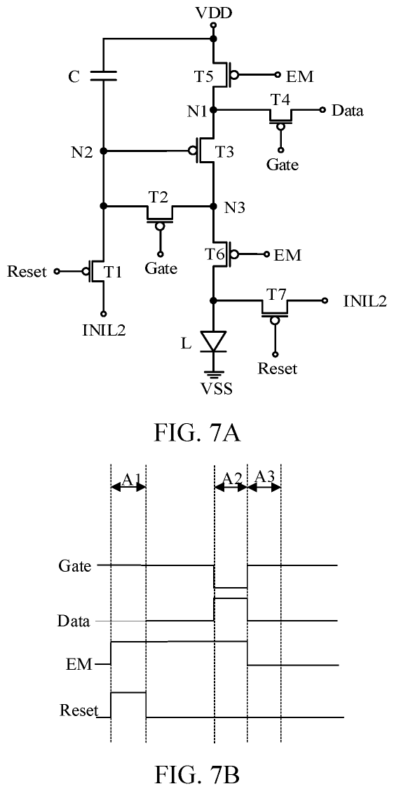

FIG. 7A is a schematic diagram of an equivalent circuit of a pixel circuit. In an exemplary implementation mode, the pixel circuit may have a structure of 3T1C, 4T1C, 5T1C, 5T2C, 6T1C, 7T1C, or 8T1C. The pixel circuit of an exemplary implementation is described by taking a 7T1C structure as an example. However, the embodiment is not limited thereto.

In an exemplary implementation mode, as shown in FIG. 7A, the pixel circuit according to the example may include seven transistors (i.e., a first transistor T1 to a seventh transistor T7) and one capacitor C. Pixel circuits are connected with 8 signal lines (for example, including: a data signal line Data, a scan signal line Gate, a reset signal line Reset, a light emitting signal line EM, a first initial signal line INIL1, a second initial signal line INIL2, a high-voltage power supply line VDD and a low-voltage power supply line VSS), respectively.

In an exemplary implementation, as shown in FIG. 7A, a gate of the first transistor Tl is electrically connected to the reset signal line Reset, a first electrode of the first transistor Tl is electrically connected to the first initial signal line INIL1, and a second electrode of the first transistor T1 is electrically connected to a gate of the third transistor T3. A gate of the second transistor T2 is electrically connected with the scan signal line Gate, a first electrode of the second transistor T2 is electrically connected with the gate of the third transistor T3, and a second electrode of the second transistor T2 is electrically connected with a second electrode of the third transistor T3. The gate of the third transistor T3 is connected with a first node N1, a first electrode of the third transistor T3 is connected with a second node N2, and the second electrode of the third transistor T3 is connected with a third node N3. The third transistor T3 may be referred to as a drive transistor, and the third transistor T3 determines an amount of a drive current flowing between the high-voltage power supply line VDD and the low-voltage power supply line VSS according to a potential difference between the gate and the first electrode of the third transistor T3. A gate electrode of the fourth transistor T4 is electrically connected with the scan signal line Gate, a first electrode of the fourth transistor T4 is electrically connected with the data signal line Data, a second electrode of the fourth transistor T4 is electrically connected with a first electrode of the third transistor T3. The fourth transistor may be a writing transistor. A gate of the fifth transistor T5 is electrically connected with the light emitting signal line EM, a first electrode of the fifth transistor T5 is electrically connected with the high-voltage power supply line VDD, and a second electrode of the fifth transistor T5 is electrically connected with the first electrode of the third transistor T3. The fifth transistor may be a first light emitting transistor. A gate electrode of a sixth transistor T6 is electrically connected with the light emitting signal line EM, a first electrode of the sixth transistor T6 is electrically connected with the second electrode of the third transistor T3, and a second electrode of the sixth transistor T6 is electrically connected with an anode of the light emitting device L. The sixth transistor T6 may be a second light emitting transistor. A gate electrode of the seventh transistor T7 is electrically connected with the reset signal line Reset, a first electrode of the seventh transistor T7 is electrically connected with the second initial signal line INIL2, and a second electrode of the seventh transistor T7 is electrically connected with the anode of the light emitting device L. A first electrode plate of the capacitor C is electrically connected to the gate electrode of the third transistor T3, and a second electrode plate of the capacitor C is electrically connected to the high-voltage power supply line VDD. A first electrode of the light emitting device L is connected to a fourth node N4, and a second electrode of the light emitting device L is connected to a low-voltage power supply line VSS.

In the example, the first node N1 is a connection point of the capacitor C, the first transistor T1, the third transistor T3, and the second transistor T2, the second node N2 is a connection point of the fifth transistor T5, the fourth transistor T4, and the third transistor T3, the third node N3 is a connection point of the third transistor T3, the second transistor T2, and the sixth transistor T6, and the fourth node N4 is a connection point of the sixth transistor T6, the seventh transistor T7, and the light emitting device L.

In an exemplary implementation mode, the seven transistors of the pixel circuit may be P-type transistors, or may be N-type transistors. Adopting a same type of transistors in the pixel circuit may simplify a process flow, reduce process difficulties of the display panel, and improve a yield of products. In some possible implementation modes, the seven transistors in the pixel circuit may include a P-type transistor and an N-type transistor.

In an exemplary implementation mode, for the seven transistors in the pixel circuit, a low temperature poly silicon thin film transistor may be adopted, or an oxide thin film transistor may be adopted, or a low temperature poly silicon thin film transistor and an oxide thin film transistor may be adopted. Low Temperature Poly-Silicon (LTPS for short) is used as an active layer of low temperature Poly-Silicon thin film transistor, and Indium Gallium Zinc Oxide (IGZO for short) is used as an active layer of oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display panel, that is, an LTPS+IGZO (LTPO for short) display panel, so that advantages of both the low temperature poly silicon thin film transistor and the oxide thin film transistor may be utilized, low-frequency drive may be achieved, power consumption may be reduced, and display quality may be improved.

In an exemplary implementation, the high-voltage power supply line VDD may be configured to provide a constant first voltage signal to the pixel circuit, and the low-voltage power supply line VSS may be configured to provide a constant second voltage signal to the pixel circuit, and the first voltage signal is greater than the second voltage signal. The scan signal line Gate may be configured to provide a scan signal to the pixel circuit, the data signal line Data may be configured to provide a data signal to the pixel circuit, and the light emitting signal line EM may be configured to provide a light emitting control signal to the pixel circuit. In some examples, in an n-th row of pixel circuits, the reset signal line Reset may be electrically connected with a scan signal line Gate of an (n−1)-th row of pixel circuits to be inputted with a scan signal. Herein, n is an integer greater than 0. In this way, signal lines of the display panel may be reduced, and a narrow bezel design of the display panel may be achieved. However, the embodiment is not limited thereto.

In an exemplary implementation mode, the first initial signal line INIL1 may be configured to provide a first initial signal to the pixel circuit, the second initial signal line INIL2 may be configured to provide a second initial signal to the pixel circuit. For example, the first initial signal may be different from the second initial signal. The first initial signal and the second initial signal may be constant voltage signals, and their magnitudes may be between, for example, the first voltage signal provided by the high-voltage power supply line VDD and the second voltage signal provided by the low-voltage power supply line VSS, but are not limited thereto. In other examples, the first initial signal and the second initial signal may be the same and only the first initial signal line may be provided to provide the first initial signal.

In an exemplary implementation, the light emitting device L may be an OLED including a first electrode (anode), an organic emitting layer, and a second electrode (cathode) which are stacked, or may be a QLED including a first electrode (anode), a quantum dot emitting layer, and a second electrode (cathode) which are stacked. A second electrode of the light emitting device is connected with the low-voltage power supply line VSS, a signal of the low-voltage power supply line VSS is a low-level signal provided continuously, and a signal of the high-voltage power supply line VDD is a high-level signal provided continuously.

In an exemplary implementation mode, FIG. 7B is a working timing diagram of a pixel circuit, as shown in FIG. 7A and FIG. 7B, taking a case in which the first transistor T1 to the seventh transistor T7 included in the pixel circuit are all P-type transistors as an example, a working process of the pixel circuit may include following stages.

The first stage A1 is referred to as a reset stage. A low-level signal provided by the reset signal line Reset enables the first transistor T1 to be turned on, and a first initial signal provided by the first initial signal line INIL1 is provided to the first node N1 to initialize the first node N1 and clear an original data voltage in the capacitor C. The scan signal line Gate provides a high-level signal and the light emitting signal line EM provides a high-level signal, so that the fourth transistor T4, the second transistor T2, the fifth transistor T5, the sixth transistor T6, and the seventh transistor T7 are turned off. The light emitting device L does not emit light in this stage

A second stage A2 is referred to as a data writing stage or a threshold compensation stage. The scan signal line Gate provides a low-level signal, the Reset signal line Reset and the light emitting signal line EM both provide a high-level signal, and the data signal line DATA outputs a data signal Date. In this stage, since the first electrode plate of the capacitor C is at a low level, the third transistor T3 is turned on. The scan signal line Gate provides the low-level signal, so that the second transistor T2, the fourth transistor T4, and the seventh transistor T7 are turned on. The second transistor T2 and the fourth transistor T4 are turned on, so that a data voltage Vdata output by the data signal line Data is provided to the first node N1 through the second node N2, the turned-on third transistor T3, the third node N3, and the turned-on second transistor T2, and the capacitor C is charged with a difference between the data voltage Vdata output by the data signal line Data and a threshold voltage of the third transistor T3. A voltage of the first electrode plate (i.e., the first node N1) of the capacitor C is Vdata−|Vth|, wherein Vdata is the data voltage output by the data signal line Data, and Vth is the threshold voltage of the third transistor T3. The seventh transistor T7 is turned on, so that a second initial signal provided by the second initial signal line INIL2 is provided to the anode of the light emitting device L to initialize (reset) the anode of the light emitting device L and clear a pre-stored voltage therein, so as to complete initialization, thereby ensuring that the light emitting device L does not emit light. The reset signal line RESET provides a high-level signal, so that the first transistor T1 is turned off. The light emitting signal line EM provides a high-level signal, so that the fifth transistor T5 and the sixth transistor T6 are turned off.

The third stage A3 is referred to as a light emitting stage. The light emitting signal line EM provides a low-level signal, and the scan signal line Gate and the Reset signal line Reset both provide a high-level signal. The light emitting signal line EM provides the low-level signal, so that the fifth transistor T5 and the sixth transistor T6 are turned on, and a first voltage signal output by the high-voltage power supply line VDD provides a drive voltage to the anode of the light emitting device L through the turned-on fifth transistor T5, the third transistor T3, and the sixth transistor T6 to drive the light emitting device L to emit light.

In a drive process of the pixel circuit, a drive current flowing through the third transistor T3 (i.e., the drive transistor) is determined by a voltage difference between the gate and the first electrode of the third transistor T3. Since the voltage of the first node N1 is Vdata−|Vth|, the drive current of the third transistor T3 is as follows.

$$I = K \times {( Vgs - Vth )}^{2} = K \times {[ ( Vdd - Vdata + \vert Vth \vert ) - Vth ]}^{2} = K \times {[ Vdd - Vdata ]}^{2}$$

Herein, I is the drive current flowing through the third transistor T3, that is, a drive current for driving the light emitting device L, K is a constant, Vgs is the voltage difference between the gate and the first electrode of the third transistor T3, Vth is the threshold voltage of the third transistor T3, Vdata is the data voltage output by the data signal line DATA, and Vdd is the first voltage signal output by the high-voltage power supply line VDD.

It may be seen from the above formula that a current flowing through the light emitting device L is independent of the threshold voltage of the third transistor T3. The pixel circuit of the embodiment may better compensate the threshold voltage of the third transistor T3.

With development of OLED display technologies, consumers have higher requirements on a display effect of a display product. An extremely narrow bezel has become a new trend in development of display products. Therefore, bezel narrowing or even no-bezel design has attracted more and more attention in a design of an OLED display product. In a display panel, a peripheral region generally includes a fan-out region, a bending region, a drive chip bonding region, and a bonding pin region sequentially arranged along a direction away from a display region. Since the fan-out region is located at a side of the bending region close to the display region, the fan-out region cannot be bent after the peripheral region is bent, so that a width difference between the display region and the peripheral region is larger, which makes it difficult to narrow the lower bezel, and the lower bezel is always maintained at about 2.0 mm.

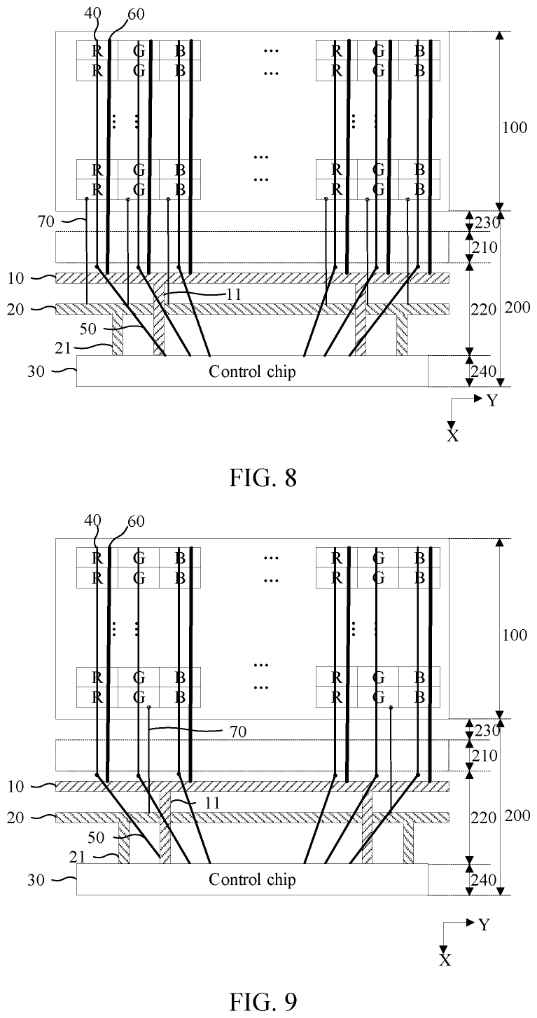

FIG. 8 is a first schematic diagram of a structure of a display panel provided according to an embodiment of the present disclosure, and FIG. 9 is a second schematic diagram of a structure of a display panel provided according to an embodiment of the present disclosure. As shown in FIG. 8 and FIG. 9, the display panel provided according to an embodiment of the present disclosure may include a display region 100 and a peripheral region 200 located at a side of the display region 100, wherein the peripheral region 200 includes a bending region 210 and a fan-out region 220; and the fan-out region 220 is located at a side of the bending region 210 away from the display region 100. The display panel may include a base substrate and circuit units arranged in an array and provided on the base substrate, a plurality of data signal lines 40 extending along the first direction X, and a plurality of data fan-out lines 50 located in the fan-out region 220.

In an exemplary implementation, as shown in FIG. 8 and FIG. 9, data signal lines 40 may extend from the display region 100 to at least the bending region 210, and are electrically connected to circuit units and data fan-out lines 50, respectively. FIG. 8 and FIG. 9 are illustrated by taking that the data signal lines 40 extend to the fan-out region 220 as an example.

In an exemplary implementation, as shown in FIG. 8 and FIG. 9, the number of the data signal lines 40 and the number of the data fan-out lines 50 are the same and are in one-to-one correspondence, and the data signal lines are electrically connected to the corresponding data fan-out lines.

FIG. 8 and FIG. 9 are illustrated by taking that the data signal lines and the data fan-out lines are arranged in different layers as an example. Black dots in FIG. 8 and FIG. 9 indicate connection vias, and the data signal lines are connected to the data fan-out lines through insulation layer vias provided between the data signal lines and the data fan-out lines.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”. In an exemplary implementation, the second direction Y may be a direction pointing from the display region to the peripheral region, and an opposite direction of the second direction Y may be a direction pointing from the peripheral region to the display region.

The display panel according to an embodiment of the present disclosure includes a display region and a peripheral region located at a side of the display region, wherein the peripheral region includes a bending region and a fan-out region; the fan-out region is located at a side of the bending region away from the display region; the display panel includes: a base substrate, circuit units arranged in an array and provided on the base substrate, a plurality of data signal lines extending along the first direction X, and a plurality of data fan-out lines located in the fan-out region; the data signal lines extend from the display region to at least the bending region, and are electrically connected with the circuit units and the data fan-out lines, respectively. According to present disclosure, the fan-out region is arranged at a side of the bending region away from the display region, so that the data fan-out line is arranged on the back side of the display panel after bending, thereby reducing a space occupied by the lower bezel of the display panel, and realizing the narrow bezel.

In an exemplary implementation, as shown in FIG. 8 and FIG. 9, the display panel may further include a plurality of high-voltage power supply lines 60 extending along the first direction X, and at least one high-voltage power supply line 60 extends from the display region 100 to the fan-out region 220.

In an exemplary implementation, as shown in FIG. 8 and FIG. 9, the number of high-voltage power supply lines 60 may be the same as or different from the number of data signal lines 40 and may be determined according to the structure of the display panel.

In an exemplary implementation, as shown in FIG. 8 and FIG. 9, a plurality of circuit units extending along the first direction X are a column of circuit units, a high-voltage power supply line is electrically connected with a column of circuit units, and at least one high-voltage power supply line is electrically connected with a plurality of columns of circuit units.

In an exemplary implementation, paths, through which high-voltage signals flow, of the circuit units arranged in an array, are communicated with each other, wherein the high-voltage signals are signals provided by the high-voltage power supply line 60. The paths, through which the high-voltage signals flow, may refer to an electrode plate of a capacitor connected to the high-voltage power supply line and a first electrode of the fifth transistor in each circuit unit. The communication with each other among the paths, through which the high-voltage signals flow, of the circuit units arranged in an array, may be a connection with each other among electrode plates of the capacitors connected to the high-voltage power supply lines of the circuit units arranged in an array and/or a connection with each other among the first electrodes of the fifth transistors. The high-voltage power supply lines may be electrically connected to other columns of circuit units through a path, through which the high-voltage signals flow, of the connected circuit unit and other circuit units.

In an exemplary implementation, as shown in FIG. 8 and FIG. 9, the display panel may further include a plurality of light emitting devices and a plurality of low-voltage power supply lines 70 extending along the first direction X, which extend from the display region 100 to the fan-out region 220, and the circuit units are electrically connected to the light emitting devices.

In an exemplary implementation, as shown in FIG. 8 and FIG. 9, the cathodes of the light emitting devices to which the multiple circuit units are connected are the same electrode and are planar electrodes.

In an exemplary implementation, as shown in FIG. 8 and FIG. 9, the number of low-voltage power supply lines 70 may be the same as or different from the number of data signal lines 40 and may be determined according to the structure of the display panel.

In an exemplary implementation, as shown in FIG. 8 and FIG. 9, a length of the low-voltage power supply line 70 along the first direction X is smaller than a length of the high-voltage power supply line 60 along the first direction X.

In an exemplary implementation, as shown in FIG. 8 and FIG. 9, a plurality of low-voltage power supply lines are electrically connected to cathodes of the light emitting devices to which a plurality of column circuit units are connected. Exemplarily, as shown in FIG. 8 and FIG. 9, the low-voltage power supply line 70 may be connected to the cathode of the light emitting device through an insulation layer via arranged between the low-voltage power supply line 70 and the cathode of the light emitting device.

In an exemplary implementation, the number of high-voltage power supply lines extending to the fan-out region and the number of low-voltage power supply lines extending to the fan-out region may be equal to the number of data signal lines, respectively, or the sum of the number of high-voltage power supply lines extending to the fan-out region and the number of low-voltage power supply lines extending to the fan-out region is equal to the number of data signal lines, or the sum of the number of high-voltage power supply lines extending to the fan-out region and the number of low-voltage power supply lines extending to the fan-out region is less than the number of data signal lines. FIG. 8 is illustrated by taking that the number of high-voltage power supply lines extending to the fan-out region and the number of low-voltage power supply lines extending to the fan-out region may be equal to the number of data signal lines, respectively as an example. FIG. 9 is illustrated by taking that the sum of the number of high-voltage power supply lines extending to the fan-out region and the number of low-voltage power supply lines extending to the fan-out region is equal to the number of data signal lines as an example.

In an exemplary implementation, as shown in FIG. 8, the i-th high-voltage power supply line 60 and the i-th low-voltage power supply line 70 are respectively located at opposite sides of the i-th data signal line 40, wherein 1≤Si≤N, and N is the number of data signal lines, that is, the i-th data signal line 40 is located between the i-th high-voltage power supply line 60 and the i-th low-voltage power supply line 70. According to the present disclosure, the i-th high-voltage power supply line 60 and the i-th low-voltage power supply line 70 are located at opposite sides of the i-th data signal line 40, respectively, which may make high-voltage signals and low-voltage signals interspersed between the adjacent data signal lines, so the interference between the adjacent data signal lines is small, which may effectively reduce image sticking, improving the display effect of the display panel.

In an exemplary implementation, the m-th high-voltage power supply line 60 extending to the fan-out region 220 is connected to the (2m−1)-th column of circuit units, the m-th high-voltage power supply line 60 extending to the fan-out region 220 is located between the (2m−1)-th data signal line 40 and the (2m)-th data signal line 40, the n-th low-voltage power supply line 70 is located between the (2n)-th data signal line 40 and the (2n+1)-th data signal line 40, or the m-th high-voltage power supply line 60 extending to the fan-out region 220 is connected to the (2m)-th column of circuit units, and the m-th high-voltage power supply line 60 extending to the fan-out region 220 is located between the (2m)-th data signal line 40 and the (2m+1)-th data signal line 40, the n-th low-voltage power supply line 70 is located between the (2n−1)-th data signal line 40 and the (2n)-th data signal line 40, wherein 1≤m≤N1, 1≤n≤N2, N1 is the number of high-voltage power supply lines extending to the fan-out region, and N2 is the number of low-voltage power supply lines. According to the present disclosure, the arrangement of the high-voltage power supply lines 60 and the low-voltage power supply lines 70 extending to the fan-out region 220 may make high-voltage signals or low-voltage signals interspersed between adjacent data signal lines, so the interference between adjacent data signal lines is small, which may effectively reduce image sticking, improving the display effect of the display pane. FIG. 9 is illustrated by taking that an m-th high-voltage power supply line 60 extending to the fan-out region 220 is connected to the (2m−1)-th column of circuit units, an m-th high-voltage power supply line 60 extending to the fan-out region 220 is located between the (2m−1)-th data signal line 40 and the (2m)-th data signal line 40, and an n-th low-voltage power supply line 70 is located between the (2n)-th data signal line 40 and the (2n+1)-th data signal line 40 as an example.

In an exemplary implementation, a plurality of high-voltage power supply lines extending to the fan-out region 220 may be uniformly arranged or non-uniformly arranged and may be defined according to the structure of the display panel, which are not limited in the present disclosure. A plurality of low-voltage power supply lines extending to the fan-out region 220 may be uniformly arranged or non-uniformly arranged and may be defined according to the structure of the display panel, which are not limited in the present disclosure.

In an exemplary implementation, as shown in FIG. 8 and FIG. 9, the display panel may further include a high-voltage signal line 10. The high-voltage signal line 10 may be located in the fan-out region 220 and extend along a second direction Y, and the first direction X intersects with the second direction Y.

In an exemplary implementation, as shown in FIG. 8 and FIG. 9, the high-voltage signal line 10 is electrically connected to at least one high-voltage power supply line 60 extending to the fan-out region 220, and an orthographic projection of the high-voltage signal line 10 on the base substrate is overlapped with orthographic projections of the data fan-out lines 50 on the base substrate.

In an exemplary implementation, as shown in FIG. 8 and FIG. 9, a length of the high-voltage signal line 10 along the first direction X is greater than a length of the high-voltage power supply line 60 along the second direction Y.

In the present disclosure, the high-voltage signal line 10 is arranged in the fan-out region at a side of the bending region away from the display region, which may reduce the space occupied by the bezel region of the display panel and achieve the narrow bezel of the display panel.

In an exemplary implementation, as shown in FIG. 8 and FIG. 9, the display panel may further include a low-voltage signal line 20. The low-voltage signal line 70 is located in the fan-out region 220 and extends along the second direction Y.

In an exemplary implementation, as shown in FIG. 8 and FIG. 9, the low-voltage signal line 20 may be electrically connected to a plurality of low-voltage power supply lines, and an orthographic projection of the low-voltage signal line 20 on the base substrate is overlapped with orthographic projections of the data fan-out lines 50 on the base substrate.

In an exemplary implementation, as shown in FIG. 8 and FIG. 9, a length of the low-voltage signal line 20 along the first direction X is greater than a length of the low-voltage power supply line along the second direction Y.

In an exemplary implementation, tan orthographic projection of the low-voltage signal line 20 on the base substrate may not be overlapped with an orthographic projection of the high-voltage signal lines 10 on the base substrate.

In an exemplary implementation, in order to avoid mutual interference of signals between the low-voltage signal line 20 and the high-voltage signal line 10, the low-voltage signal line 20 and the high-voltage signal line 10 may be arranged in different layers, and the low-voltage signal line 20 is located at a side of the high-voltage signal line 10 away from the display region 100.

According to the present disclosure, since the arrangement of the high-voltage signal line and the low-voltage signal line makes the voltage drops of the high-voltage power supply line 60 and the low-voltage power supply line 70 reaching the circuit units of the display region substantially identical, the display uniformity of the display panel is better.

In an exemplary implementation as shown in FIG. 8 and FIG. 9, the peripheral region 200 further includes a bending transition region 230 located between the display region 100 and the bending region 210. The bending transition region may provide enough space for the bending region to bend, so as to avoid the damage of the traces located in the bending region during bending.

In an exemplary implementation, the drive circuit layer is provided with a circuit unit, a data signal line, a data fan-out line, a high-voltage power supply line, a low-voltage power supply line, a high-voltage signal line and a low-voltage signal line, the light emitting structure layer is provided with a light emitting device, and the drive circuit layer includes a first conductive layer, a second conductive layer, a third conductive layer and a fourth conductive layer which are sequentially stacked on the base substrate.

In an exemplary implementation, the first conductive layer may include one electrode plate of the capacitor and gate electrodes of a plurality of transistors, the second conductive layer may include the other electrode plate of the capacitor, and the third conductive layer may include source electrodes and drain electrodes of the plurality of transistors.

In an exemplary implementation, the drive circuit layer may further include a semiconductor layer located at a side of the first conductive layer close to the base substrate. The semiconductor layer may include active layers of a plurality of transistors.

In an exemplary implementation, the drive circuit layer may further include a plurality of insulation layers and a planarization layer, wherein the plurality of insulation layers may include a first insulation layer arranged between the semiconductor layer and the first conductive layer, a second insulation layer arranged between the first conductive layer and the second conductive layer, a third insulation layer arranged between the second conductive layer and the third conductive layer, a fourth insulation layer arranged between the third conductive layer and the fourth conductive layer, and a fifth insulation layer arranged at a side of the fourth conductive layer away from the base substrate.

In an exemplary implementation, the semiconductor layer may be made of a material, such as an amorphous indium gallium zinc oxide material (a-IGZO), zinc oxynitride (ZnON), indium zinc tin oxide (IZTO), amorphous silicon (a-Si), polycrystalline silicon (p-Si), sexithiophene or polythiophene, that is, the present disclosure is applicable to transistors manufactured based on the oxide technology, silicon technology or organic technology.

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation, the first insulation layer, the second insulation layer, the third insulation layer, the fourth insulation layer and the fifth insulation layer may be made of any one or more of silicon oxide (SiOx), silicon nitride (SiNx) and silicon oxynitride (SiON), and may be in a single layer, multiple layers, or in a composite layer. The first insulation layer may be referred to as a buffer layer, the second insulation layer may be referred to as a gate insulation (GI) layer, the fourth insulation layer may be referred to as an interlayer dielectric (ILD) layer, and the fifth insulation layer may be referred to as a passivation (PVX) layer.

In an exemplary implementation, an anode of the light emitting device may employ a transparent conductive layer, which may be made of Indium tin oxide ITO or indium zinc oxide IZO, or employ a multi-layer composite structure, such as ITO/Ag/ITO.

In an exemplary implementation, the planarization layer may be made of an organic material, such as resin.

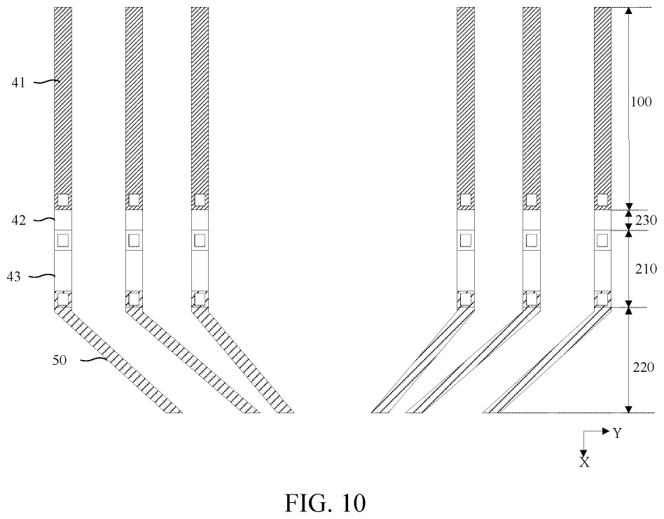

FIG. 10 is a first schematic diagram of a partial film layer of a display panel. As shown in FIG. 10, in an exemplary implementation, the data signal lines 40 may include: a first data signal line 41 located at least in the display region 100, a second data signal line 42 located at least in the bending transition region 230, and a third data signal line 43 located at least in the bending region 210.

In an exemplary implementation, as shown in FIG. 10, the second data signal line 42 is arranged in a layer different from the first data signal line 41 and the third data signal line 43, respectively, the third data signal line 43 is arranged in a layer different from the data fan-out line 50, an orthographic projection of the second data signal line 42 on the base substrate is partially overlapped with an orthographic projection of the first data signal line 41 and an orthographic projection of the third data signal line 43 on the base substrate, respectively, the orthographic projection of the third data signal line 43 on the base substrate is partially overlapped with an orthographic projection of the data fan-out line 50 on the base substrate, the second data signal line 42 is electrically connected with the first data signal line 41 and the third data signal line 43, respectively, the first data signal line 41 is electrically connected with the circuit unit, and the third data signal line 43 is electrically connected with the data fan-out line 50.

In an exemplary implementation, the first data signal line 41 is located in the third conductive layer and/or the fourth conductive layer, the second data signal line 42 is located in the first conductive layer or the second conductive layer, the third data signal line 43 is located in the third conductive layer or the fourth conductive layer, and the data fan-out line 50 is located in the first conductive layer or the second conductive layer. FIG. 10 is illustrated by taking that the first data signal line 41 and the third data signal line 43 are located in the same film layer, the second data signal line 42 and the data fan-out line 50 are located in the same film layer, and the second data signal line 42 is also located in the display region and the bending region as an example.

In an exemplary implementation, as shown in FIG. 10, the dashed box refers to a connection hole. As shown in FIG. 10, the second data signal line 42 is electrically connected to the first data signal line 41 through a connection hole of an insulation layer arranged between the first data signal line 41 and the second data signal line 42. The second data signal line 42 is electrically connected to the third data signal line 43 through a connection hole of an insulation layer arranged between the third data signal line 43 and the second data signal line 42. The third data signal line 43 is electrically connected to the data fan-out line 50 through a connection hole of an insulation layer arranged between the third data signal line 43 and the data fan-out line 50.

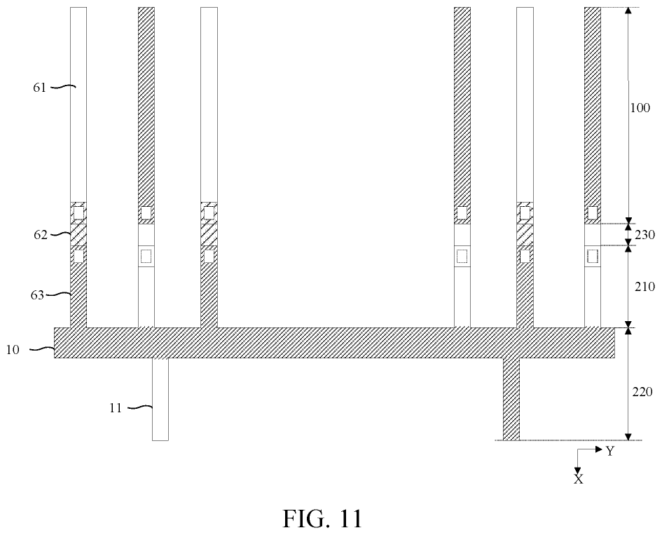

FIG. 11 is a second schematic diagram of a partial film layer of a display panel. As shown in FIG. 11, in an exemplary implementation, the high-voltage power supply line 60 may include a first high-voltage power supply line 61 located at least in the display region 100, a second high-voltage power supply line 62 located at least in the bending transition region 230, and a third high-voltage power supply line 63 located at least in the bending region 210 and the fan-out region 220.

In an exemplary implementation, as shown in FIG. 11, the second high-voltage power supply line 62 is arranged in a layer different from the first high-voltage power supply line 61 and the third high-voltage power supply line 63, respectively, the third high-voltage power supply line 63 is arranged in the same layer as the high-voltage signal line 10, an orthographic projection of the second high-voltage power supply line 62 on the base substrate is partially overlapped with an orthographic projection of the first high-voltage power supply line 61 on the base substrate and an orthographic projection of the third high-voltage power supply line 63 on the base substrate, respectively, the second high-voltage power supply line 62 is electrically connected with the first high-voltage power supply line 61 and the third high-voltage power supply line 63, respectively, the first high-voltage power supply line 61 is electrically connected with the circuit unit, and the third high-voltage power supply line 63 is electrically connected with the high-voltage signal line 10.

In an exemplary implementation, the first high-voltage power supply line 61 is located in the third conductive layer and/or the fourth conductive layer, the second high-voltage power supply line 62 is located in the first conductive layer or the second conductive layer, and the third high-voltage power supply line 63 is located in the third conductive layer or the fourth conductive layer.

In an exemplary implementation, as shown in FIG. 11, the dashed box refers to a connection hole. The second high-voltage power supply line 62 is electrically connected to the first high-voltage power supply line 61 through a connection hole of an insulation layer arranged between the first high-voltage power supply line 61 and the second high-voltage power supply line 62. The second high-voltage power supply line 62 is electrically connected to the third high-voltage power supply line 63 through a connection hole of an insulation layer arranged between the third high-voltage power supply line 63 and the second high-voltage power supply line 62.

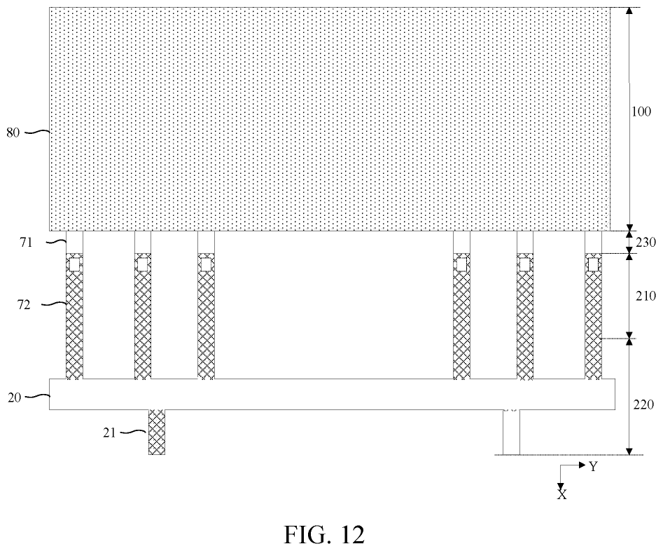

FIG. 12 is a third schematic diagram of a partial film layer of a display panel. As shown in FIG. 12, in an exemplary implementation, the low-voltage power supply lines 70 include a first low-voltage power supply line 71 located at least in the display region 100 and the bending transition region 230 and a second low-voltage power supply line 72 located at least in the bending region 210 and the fan-out region 220.

In an exemplary implementation, as shown in FIG. 12, the first low-voltage power supply line 71 and the second low-voltage power supply line 72 are arranged in different layers, the second low-voltage power supply line 72 and the low-voltage signal line 20 are arranged in the same layer, an orthographic projection of the first low-voltage power supply line 71 on the base substrate is partially overlapped with an orthographic projection of the cathode 80 on the base substrate and an orthographic projection of the second low-voltage power supply line 72 on the base substrate, respectively, and the first low-voltage power supply line 71 is electrically connected to the cathode of the light emitting device and the second low-voltage power supply line 72, respectively.

In an exemplary implementation, the first low-voltage power supply line 71 is located in the first conductive layer or the second conductive layer; the second low-voltage power supply line 72 is located in the third conductive layer or the fourth conductive layer.

In an exemplary implementation, as shown in FIG. 12, the dashed box refers to a connection hole. The first low-voltage power supply line 71 is electrically connected to the cathode of the light emitting device through a connection hole of an insulation layer provided between the first low-voltage power supply line 71 and the cathode of the light emitting device. The first low-voltage power supply line 71 is electrically connected to the second low-voltage power supply line 72 through a connection hole of an insulation layer arranged between the first low-voltage power supply line 71 and the second low-voltage power supply line 72.

In an exemplary implementation, the first low-voltage power supply line 71 and the second high-voltage power supply line 62 may be arranged in the same layer or in different layers.

In an exemplary implementation, the second low-voltage power supply line is located in the fourth conductive layer when the third high-voltage power supply line 63 is located in the third conductive layer, or the second low-voltage power supply line is located in the third conductive layer when the third high-voltage power supply line 63 is located in the fourth conductive layer.

In an exemplary implementation, as shown in FIG. 8 to FIG. 12, the peripheral region 200 may further include a driver chip bonding region 240 located at a side of the fan-out region 220 away from the display region 100, wherein the driver chip bonding region 240 includes a control chip 30, and the display panel further includes at least one high-voltage connection line 11 extending along the first direction X and at least one low-voltage connection line 21 extending along the first direction X. FIG. 8 to FIG. 12 are illustrated by taking that the display panel includes two high-voltage connection lines 11 and two low-voltage connection lines 21 as an example.

In the exemplary implementation, as shown in FIG. 8 to FIG. 12, the high-voltage connection line 11 is electrically connected to the high-voltage signal line 10 and the control chip 30, respectively, and the low-voltage connection line 21 is electrically connected to the low-voltage signal line 20 and the control chip 30, respectively.

In an exemplary implementation, the high-voltage connection line 11 and the high-voltage signal line 10 may be arranged in the same layer, and the low-voltage connection line 21 and the low-voltage signal line 20 may be arranged in the same layer. The high-voltage connection line 11 and the high-voltage signal line 10 may be arranged in the same layer, and the low-voltage connection line 21 and the low-voltage signal line 20 may be arranged in the same layer, such that the manufacturing process of the display panel may be simplified.

In an exemplary implementation, the display panel of the present disclosure may be applied to a display apparatus with a pixel circuit, such as an OLED, a Quantum dot display (QLED), a Micro Light Emitting Diode display (Micro LED or Mini LED), or a Quantum Dot Light Emitting Diode display (QD-LED), which is not limited here in the present disclosure.

Through simulation, the uniformity of the current of the display panel according to an embodiment of the present disclosure in different items is greater than 75%. In the simulation, it is obtained by selecting 9 positions in the display panel, and analyzing the currents of high-voltage power supply lines and low-voltage power supply lines at these 9 positions. For a display panel with high resolution (for example, 2436*2752, and the pixel unit includes 4 sub-pixels), the uniformity of the current is up to 93% or more. Therefore, through simulation, the display uniformity of the display panel according to an embodiment of the present disclosure is high.

An embodiment of the present disclosure further provides a display apparatus which includes a display panel provided according to any one of the aforementioned embodiments.

In an exemplary implementation mode, the display apparatus may be any product or component with a display function, such as a mobile phone, a tablet computer, a television, a display, a laptop computer, a digital photo frame, or a navigator, and the present disclosure is not limited thereto.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display panel comprising: a display region and a peripheral region located at a side of the display region, wherein the peripheral region comprises a bending region and a fan-out region; the fan-out region is located at a side of the bending region away from the display region; the display panel comprises: a base substrate, circuit units arranged in an array and provided on the base substrate, a plurality of data signal lines extending along a first direction, and a plurality of data fan-out lines located in the fan-out region;
the data signal lines extend from the display region to at least the bending region, and are electrically connected with the circuit units and the data fan-out lines, respectively.

2. The display panel according to claim 1, further comprising: a plurality of high-voltage power supply lines extending along the first direction, wherein at least one high-voltage power supply line extends from the display region to the fan-out region;
a plurality of circuit units extending along the first direction are a column of circuit units, one high-voltage power supply line is electrically connected with a column of circuit units, and the at least one high-voltage power supply line is electrically connected with a plurality of columns of circuit units.

3. The display panel according to claim 2, further comprising: a plurality of light emitting devices and a plurality of low-voltage power supply lines extending along the first direction, wherein the low-voltage power supply lines extend from the display region to the fan-out region, and the circuit unit are electrically connected to the light emitting devices;
the plurality of low-voltage power supply lines are electrically connected with cathodes of the light emitting devices connected to a plurality of columns of circuit units.

4. The display panel according to claim 3, wherein a number of high-voltage power supply lines extending to the fan-out region and a number of low-voltage power supply lines extending to the fan-out region are equal to a number of data signal lines, respectively;
an i-th high-voltage power supply line and an i-th low-voltage power supply line are located at opposite sides of an i-th data signal line, respectively, wherein 1≤i≤N, and N is a number of data signal lines.

5. The display panel according to claim 3, wherein a sum of a number of high-voltage power supply lines extending to the fan-out region and a number of low-voltage power supply lines extending to the fan-out region is equal to a number of data signal lines;
an m-th high-voltage power supply line extending to the fan-out region is connected to a (2m−1)-th column of circuit units, the m-th high-voltage power supply line extending to the fan-out region is located between a (2m−1)-th data signal line and a (2m)-th data signal line, an n-th low-voltage power supply line is located between a (2n)-th data signal line and a (2n+1)-th data signal line, or the m-th high-voltage power supply line extending to the fan-out region is connected to a (2m)-th column of circuit units, the m-th high-voltage power supply line extending to the fan-out region is located between a (2m)-th data signal line and a (2m+1)-th data signal line, the n-th low-voltage power supply line is located between a (2n−1)-th data signal line and the (2n)-th data signal line, wherein 1m≤N1, 1≤n≤N2, N1 is a number of high-voltage power supply lines extending to the fan-out region, and N2 is a number of low-voltage power supply lines.

6. The display panel according to claim 3, further comprising: a high-voltage signal line located in the fan-out region and extending along a second direction, wherein the first direction intersects with the second direction;
the high-voltage signal line is electrically connected with at least one high-voltage power supply line extending to the fan-out region, and an orthographic projection of the high-voltage signal line on the base substrate is overlapped with orthographic projections of the data fan-out lines on the base substrate;
a length of the high-voltage signal line along the first direction is greater than lengths of the high-voltage power supply lines along the second direction.

7. The display panel according to claim 6, further comprising: a low-voltage signal line located in the fan-out region and extending along the second direction;
the low-voltage signal line is electrically connected with a plurality of low-voltage power supply lines, and an orthographic projection of the low-voltage signal line on the base substrate is overlapped with the orthographic projections of the data fan-out lines on the base substrate;
a length of the low-voltage signal line along the first direction is greater than lengths of the low-voltage power supply lines along the second direction.

8. The display panel according to claim 7, wherein the low-voltage signal line and the high-voltage signal line are arranged in different layers;
in the fan-out region, the low-voltage signal line is located at a side of the high-voltage signal line away from the bending region.

9. The display panel according to claim 8, wherein the peripheral region further comprises: a bending transition region located between the display region and the bending region;
the data signal lines comprise: a first data signal line located at least in the display region, a second data signal line located at least in the bending transition region and a third data signal line located at least in the bending region;
the second data signal line is arranged in a layer different from the first data signal line and the third data signal line, respectively, the third data signal line and a data fan-out line are arranged in different layers, an orthographic projection of the second data signal line on the base substrate is partially overlapped with an orthographic projection of the first data signal line and an orthographic projection of the third data signal line on the base substrate, respectively, the orthographic projection of the third data signal line on the base substrate is partially overlapped with the orthographic projection of the data fan-out line on the base substrate, the second data signal line is electrically connected with the first data signal line and the third data signal line, respectively, the first data signal line is electrically connected with the circuit units, and the third data signal line is electrically connected with the data fan-out line.

10. The display panel according to claim 9, wherein the high-voltage power supply lines comprise: a first high-voltage power supply line located at least in the display region, a second high-voltage power supply line located at least in the bending transition region, and a third high-voltage power supply line located at least in the bending region and the fan-out region;
the second high-voltage power supply line is arranged in a layer different from the first high-voltage power supply line and the third high-voltage power supply line, respectively, the third high-voltage power supply line is arranged in a same layer with the high-voltage signal line, an orthographic projection of the second high-voltage power supply line on the base substrate is partially overlapped with an orthographic projection of the first high-voltage power supply line on the base substrate and an orthographic projection of the third high-voltage power supply line on the base substrate, respectively, the second high-voltage power supply line is electrically connected with the first high-voltage power supply line and the third high-voltage power supply line, respectively, the first high-voltage power supply line is electrically connected with the circuit units, and the third high-voltage power supply line is electrically connected with the high-voltage signal line.

11. The display panel according to claim 10, wherein the low-voltage power supply lines comprise: a first low-voltage power supply line located at least in the display region and the bending transition region and a second low-voltage power supply line located at least in the bending region and the fan-out region;
the first low-voltage power supply line and the second low-voltage power supply line are arranged in different layers, the second low-voltage power supply line and the low-voltage signal line are arranged in a same layer, an orthographic projection of the first low-voltage power supply line on the base substrate is partially overlapped with orthographic projections of cathodes of the light emitting devices on the base substrate and an orthographic projection of the second low-voltage power supply line on the base substrate, respectively, the first low-voltage power supply line is electrically connected with the cathodes of the light emitting devices and the second low-voltage power supply line, respectively, and the second low-voltage power supply line is electrically connected with the low-voltage signal line.

12. The display panel according to claim 11, further comprising: a drive circuit layer and a light emitting structure layer arranged on the base substrate, wherein the drive circuit layer is provided with a circuit unit, a data signal line, a data fan-out line, a high-voltage power supply line, a low-voltage power supply line, a high-voltage signal line and a low-voltage signal line, the light emitting structure layer is provided with a light emitting device, and the drive circuit layer comprises a first conductive layer, a second conductive layer, a third conductive layer and a fourth conductive layer which are sequentially stacked on the base substrate;
the first data signal line is located in the third conductive layer and/or the fourth conductive layer, the second data signal line is located in the first conductive layer or the second conductive layer, the third data signal line is located in the third conductive layer or the fourth conductive layer, and the data fan-out line is located in the first conductive layer or the second conductive layer.

13. The display panel according to claim 12, wherein the first high-voltage power supply line is located in the third conductive layer and/or the fourth conductive layer, the second high-voltage power supply line is located in the first conductive layer or the second conductive layer, and the third high-voltage power supply line is located in the third conductive layer or the fourth conductive layer.

14. The display panel according to claim 12, wherein the first low-voltage power supply line is located in the first conductive layer or the second conductive layer; and the second low-voltage power supply line is located in the third conductive layer or the fourth conductive layer.

15. The display panel according to claim 13, wherein the peripheral region further comprises: a drive chip bonding region located at a side of the fan-out region away from the display region, the drive chip bonding region comprises: a control chip, and the display panel further comprises: at least one high-voltage connection line extending along the first direction and at least one low-voltage connection line extending along the first direction;
the high-voltage connection line is electrically connected with the high-voltage signal line and the control chip, respectively, and the low-voltage connection line is electrically connected with the low-voltage signal line and the control chip, respectively.

16. The display panel according to claim 15, wherein the high-voltage connection line and the high-voltage signal line are arranged in a same layer, and the low-voltage connection line and the low-voltage signal line are arranged in a same layer.

17. A display apparatus, comprising: the display panel according to claim 1.

18. The display panel according to claim 4, further comprising: a high-voltage signal line located in the fan-out region and extending along a second direction, wherein the first direction intersects with the second direction;
the high-voltage signal line is electrically connected with at least one high-voltage power supply line extending to the fan-out region, and an orthographic projection of the high-voltage signal line on the base substrate is overlapped with orthographic projections of the data fan-out lines on the base substrate;
a length of the high-voltage signal line along the first direction is greater than lengths of the high-voltage power supply lines along the second direction.

19. The display panel according to claim 5, further comprising: a high-voltage signal line located in the fan-out region and extending along a second direction, wherein the first direction intersects with the second direction;
the high-voltage signal line is electrically connected with at least one high-voltage power supply line extending to the fan-out region, and an orthographic projection of the high-voltage signal line on the base substrate is overlapped with orthographic projections of the data fan-out lines on the base substrate;
a length of the high-voltage signal line along the first direction is greater than lengths of the high-voltage power supply lines along the second direction.

20. The display panel according to claim 14, wherein the peripheral region further comprises: a drive chip bonding region located at a side of the fan-out region away from the display region, the drive chip bonding region comprises: a control chip, and the display panel further comprises: at least one high-voltage connection line extending along the first direction and at least one low-voltage connection line extending along the first direction;
the high-voltage connection line is electrically connected with the high-voltage signal line and the control chip, respectively, and the low-voltage connection line is electrically connected with the low-voltage signal line and the control chip, respectively.
